(19) United States
(12) Patent Application Publication
(10) Pub. No.: US 2006/0079100 A1
(43) Pub. Date: Apr. 13, 2006

(54) High density plasma grown silicon nitride

(75) Inventors: Pooran Chandra Joshi, Vancouver, WA (US); Apostolos T. Voutsas, Portland, OR (US); John W. Hartzell, Camas, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/218,111

(22) Filed: Sep. 1, 2005

Related U.S. Application Data
(63) Continuation-in-part of application No. 10/871,939, filed on Jun. 17, 2004.
Application No. 10/871,939 is a continuation-in-part of application No. 10/801,374, filed on Mar. 15, 2004.

(51) Int. Cl. H01L 21/469

(52) U.S. Cl. 438/791; 438/792

(57) ABSTRACT

A method is provided for forming a silicon nitride (SiNx) film. The method comprises: providing a Si substrate or Si film layer; optionally maintaining a substrate temperature of about 400 degrees C., or less; performing a high-density (HD) nitrogen plasma process where a top electrode is connected to an inductively coupled HD plasma source; and, forming a grown layer of SiNx overlying the substrate. More specifically, the HD nitrogen plasma process includes using an inductively coupled plasma (ICP) source to supply power to a top electrode, independent of the power and frequency of the power that is supplied to the bottom electrode, in an atmosphere with a nitrogen source gas. The SiNx layer can be grown at an initial growth rate of at least about 20 Å in about the first minute.

### RELATED APPLICATIONS

This application is a continuation-in-part of a pending patent application entitled, HIGH-DENSITY PLASMA PROCESS FOR SILICON THIN-FILMS, invented by Pooran Joshi, Ser. No. 10/871,939, filed Jun. 17, 2004.

This application is a continuation-in-part of a pending patent application entitled, HIGH-DENSITY PLASMA HYDROGENATION, invented by Joshi et al., Ser. No. 11/013,605, filed Dec. 15, 2004.

This application is a continuation-in-part of a pending patent application entitled, METHODS FOR FABRICATING OXIDE THIN-FILMS, invented by Joshi et al., Ser. No. 10/801,374, filed Mar. 15, 2004. These applications are incorporated herein by reference.

### BACKGROUND OF THE INVENTION

1. Field of the Invention

This invention generally relates to integrated circuit (IC) and liquid crystal display (LCD) fabrication and, more particularly, to high density plasma (HDP) nitration and HDP silicon nitride growth processes.

2. Description of the Related Art

Silicon nitride films are widely used for diverse electronic applications, exploiting their excellent insulating, dielectric, and diffusion resistance characteristics. The high dielectric constant, effective diffusion barrier resistance for dopant species, and the high breakdown field strength characteristics of silicon nitride are attractive for gate dielectric applications. Various IC applications have used silicon nitride films as oxidation and diffusion masks. Silicon nitride films exhibit an enhanced resistance to high field stress, as compared to SiO₂ thin films, and are radiation hard.

Thermal nitride grows very slowly, with a self-limiting growth due to the high diffusion resistance of the growing silicon nitride film. Typically, even after a growth time of 60 min at 1150° C., the silicon nitride film thickness is less than 40 Å. This rate of growth makes the process impractical for commercial applications.

Even this low rate of thermal growth of nitride is impractical at processing temperatures lower than 1100° C. However, thermal growth temperatures exceeding 1100° C. make the process unsuitable for low temperature devices integrated on glass, plastic, or other polymeric substrates that are often used in LCD fabrication. The high growth temperatures are also not suitable for IC applications due to serious impurity redistribution issues.

Chemical vapor deposition (CVD) processes can be used for the low temperature deposition of silicon nitride films. However, the resultant film quality and reliability are a strong function of film thickness and processing condition. The quality of a CVD nitride film degrades with decreasing film thickness and poses severe reliability issues, especially at thicknesses of less than 100 Å. Major issues associated with standard CVD thin film processing are the film density, bulk, and interfacial quality.

The plasma-enhanced CVD (PECVD) technique is also widely used for the low temperature processing of silicon nitride thin films. PECVD silicon nitride films have the problem of high hydrogen content, stress, and low density, which require further treatments to optimize the film quality.

### SUMMARY OF THE INVENTION

This invention provides a high-density plasma-based process for the low temperature growth of silicon nitride having a quality comparable to thermally grown silicon nitride thin films processed at temperatures of greater than about 1150° C. The high-density plasma process is characterized by a high plasma concentration, low plasma potential, and independent control over the plasma energy and density functions, which provides unique process possibilities and control. The high-density plasma characteristics make thin film processing possible, due to enhanced process kinetics. The low plasma potential of the high-density plasma technique is effective in minimizing any plasma-induced damage to the bulk microstructure and film/substrate interface. This invention provides a high-density plasma-based process for the growth of thermal quality nitride at a processing temperature lower than about 400° C. Additionally, the high-density plasma growth process overcomes the major limitations associated with thermal, and other thin film deposition techniques.

The silicon nitride growth rate associated with high-density plasma is significantly higher than that of the conventional thermal growth rate at a temperature of about 1150° C., and does not show any temperature dependence in the range of about 100-300° C. The high-density plasma grown nitride thin films make possible the fabrication of single layer, bilayer, or multilayer structures at a processing temperature suitable for advanced integrated circuits.

Accordingly, a method is provided for forming a silicon nitride (SiNx) film. The method comprises: providing a Si substrate or Si film layer; maintaining a substrate temperature of about 400 degrees C., or less; performing a high-density (HD) nitrogen plasma process where a top electrode is connected to an inductively coupled HD plasma source; and, forming a grown layer of SiNx overlying the substrate.

More specifically, the HD nitrogen plasma process includes using an inductively coupled plasma (ICP) source to supply power to a top electrode, independent of the power and frequency of the power that is supplied to the bottom electrode, in an atmosphere with a nitrogen source gas.

The SiNx layer is grown at an initial growth rate of at least about 20 Å in about the first minute. An overall SiNx thickness of about 50 Å can be practically formed, before the high diffusion resistance significantly affects the growth rate.

Additional details of the above-described method, a method for enhancing the nitrogen content in a SiNx film, a method for the nitridation of a substrate, and a method for nitrogen passivation of a substrate structure are presented below.

### BRIEF DESCRIPTION OF THE DRAWINGS

FIG. 1 is a block diagram depicting a high-density plasma (HDP) system employing an inductively coupled plasma source.

FIG. 2 is a graph showing the high-density plasma growth of silicon nitride in a He/N₂ (3%) atmosphere at substrate temperatures of about 100 and about 300° C.

FIG. 3 is a graph depicting the oxygen diffusion characteristics of a high-density plasma-grown silicon nitride thin film.

FIG. 4 is a diagram depicting a step in a sequential nitridation process.

FIG. 5 is a flowchart illustrating a method for forming a silicon nitride (SiNx) film.

FIG. 6 is a flowchart illustrating a method for enhancing the nitrogen (N) content in a SiNx film.

FIG. 7 is a flowchart illustrating a method for the nitridation of a substrate.

FIG. 8 is a flowchart illustrating a method for passivating the structure of a substrate.

### DETAILED DESCRIPTION

The present invention provides a high-density plasma based process for the low temperature growth of thermal quality silicon nitride films. The high-density plasma characteristics are effective in the low temperature (<about 400° C.) growth of silicon nitrides at growth rates exceeding those of thermal silicon nitride grown at temperatures of greater than about 1100° C. The active nitrogen radicals generated by the high-density plasma process are effective in dissociating the Si—Si bond on a silicon surface, and promoting the growth of silicon nitride layer at a processing temperature range of about 100-300° C.

The HDP nitride growth processes described herein can also be performed at temperatures higher than about 400° C. There are no inherent limitations to the HDP process that prevent the HDP process from being performed at temperatures greater than about 400° C., and as high as thermal process temperatures. However, the ability of the present invention process to grow high quality nitride at low temperatures, below about 400° C., is one of the features that distinguish it from conventional nitridation processes.

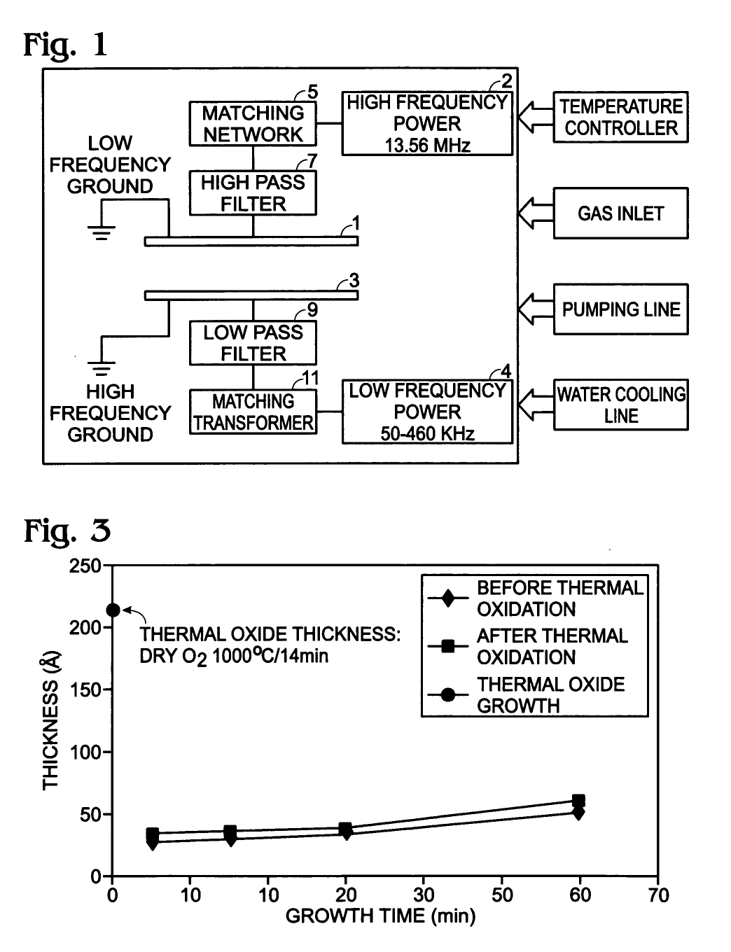

FIG. 1 is a block diagram depicting a high-density plasma (HDP) system employing an inductively coupled plasma source. The top electrode 1 is driven by a high frequency radio frequency (RF) source 2, while the bottom electrode 3 is driven by a lower frequency power source 4. The RF power is coupled to the top electrode 1, from the high-density inductively coupled plasma (ICP) source 2, through a matching network 5 and high pass filter 7. The power to the bottom electrode 3, through a low pass filter 9 and matching transformer 11, can be varied independently of the top electrode 1. The top electrode power frequency can be in the range of about 13.56 to about 300 megahertz (MHz) depending on the ICP design. The bottom electrode power frequency can be varied in the range of about 50 kilohertz (KHz) to about 13.56 MHz, to control the ion energy. The pressure can be varied up to 500 mTorr. The top electrode power can be as great as about 10 watts per square-centimeter (W/cm²), while the bottom electrode power can be as great as about 3 W/cm².

Silicon Nitride Thin Film Growth Process

The high-density plasma process is attractive for the low temperature processing of dielectric thin films because of its high plasma density, low plasma potential, and independent control of plasma energy and density. The high-density plasma growth technique is suitable for processing high quality thin films with minimal process-induced bulk and interface damage, as compared to sputtering or a conventional PECVD technique employing a capacitively coupled plasma source. The high-density plasma process is also attractive for the low-temperature processing of thin films, as the reaction kinetics are dominantly controlled by the plasma parameters, rather than by the thermal state of the substrate.

The high-density plasma characteristics are suitable for the efficient generation of active nitrogen species in the low temperature growth of silicon nitride thin films on silicon surfaces that can be nitridated. The high-density plasma energy distribution is suitable for the efficient dissociation of Si—Si bond, and for the formation of Si—N networks. The typical high-density plasma processing parameters and range for silicon nitride growth are listed in Table I. The high plasma density and low plasma potential of the high-density plasma process are effective in minimizing the bulk and interface damage, and any process-induced impurities in the deposited films.

TABLE I
High-density Plasma Processing of Silicon Nitride Thin Films

| | |
|---|---|
| Top Electrode Power | 13.56-300 MHz, up to 10 W/cm², |
| Bottom Electrode Power | 50 KHz-13.56 MHz, up to 3 W/cm² |
| Pressure | 1-500 mTorr |
| Gases: | Any suitable inert gas + Source of |
| | Nitrogen: N₂, NH3, etc. + Hydrogen |
| Alternate Gases: | He + N₂ |
| Temperature | 25-400° C. |
| Film Thickness (nm) | Up to 5 nm in one step |

Silicon Nitride Growth Rate

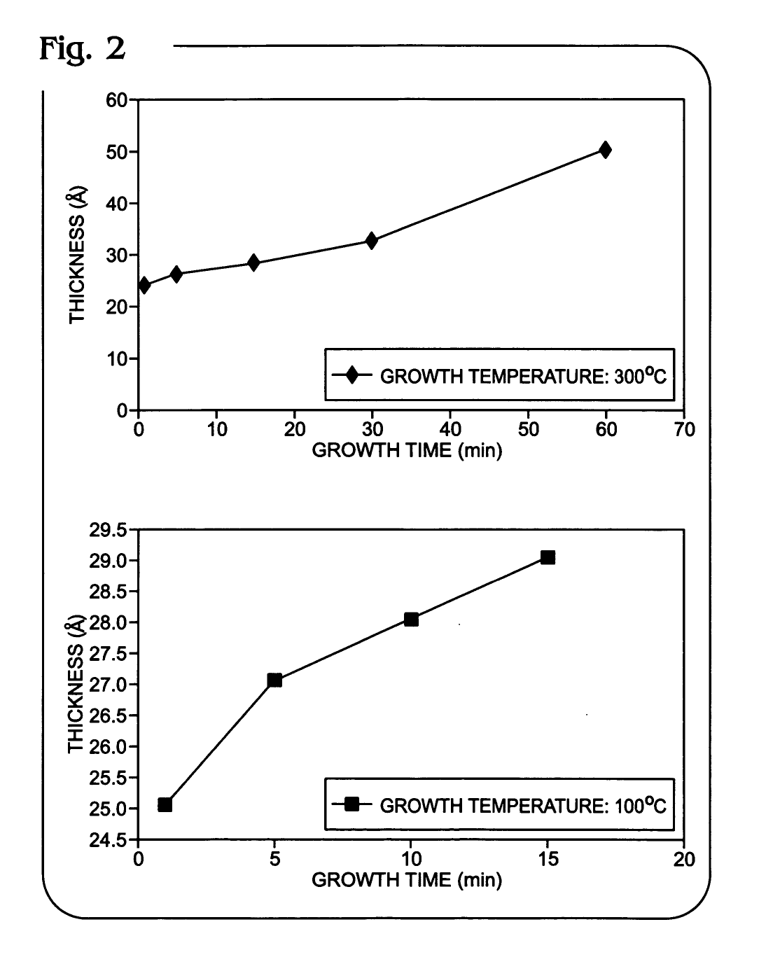

FIG. 2 is a graph showing the high-density plasma growth of silicon nitride in a He/N₂ (3%) atmosphere at substrate temperatures of about 100 and about 300° C. The high-density plasma growth of silicon nitride is significantly higher than the conventional process thermal growth rate at a temperature of about 1150° C. The silicon nitride growth rate has been measured down to an investigated substrate temperature of about 100° C., as shown in FIG. 3, suggesting that the growth kinetics are controlled by the high-density plasma, rather than by the thermal state of the substrate.

One significant aspect of the high-density plasma growth of silicon nitride is the initial rapid growth of the nitride thin film. It is possible to grow a silicon nitride thickness of about 25 Å after about 1 minute, which is significantly higher than the growth reported by conventional methods. This initial high growth rate can be exploited for the low thermal budget processing of thicker films on novel device structures. The fact that the silicon nitride growth is independent of the thermal state of the substrate suggests the suitability of the high-density plasma-based growth process for novel device development exploiting the unique properties of silicon nitride thin films.

Diffusion Resistance

FIG. 3 is a graph depicting the oxygen diffusion characteristics of a high-density plasma-grown silicon nitride thin film. The quality of the high-density plasma-grown silicon nitride thin films has been evaluated with respect to oxygen diffusion resistance at a temperature of about 1000° C. High-density plasma-grown silicon nitride films with a thickness of about 27-50 Å were subjected to a dry oxygen atmosphere to investigate the diffusion resistance. A bare Si wafer was also included as a control in the study to establish a number for the growth of oxide on Si, without a silicon nitride barrier. As shown in FIG. 3, a thermal annealing in dry O₂, at a temperature of about 1000° C., for about 14 minutes resulted in an oxide growth of about 213 Å on bare Si wafer, while no appreciable oxide growth was observed on Si wafers with about a 27-50 Å silicon nitride overlayer. The observed results show the high quality of the high-density plasma grown silicon nitride thin films, even at a processing temperature lower than about 400° C. The SiNx film can be used as thermally stable oxygen diffusion barrier for electronic devices. The diffusion barrier film can be formed at low temperatures on any structure by depositing a Si layer, and then converting it into SiNx film by high-density plasma nitridation.

Growth of Thick Nitride Layer

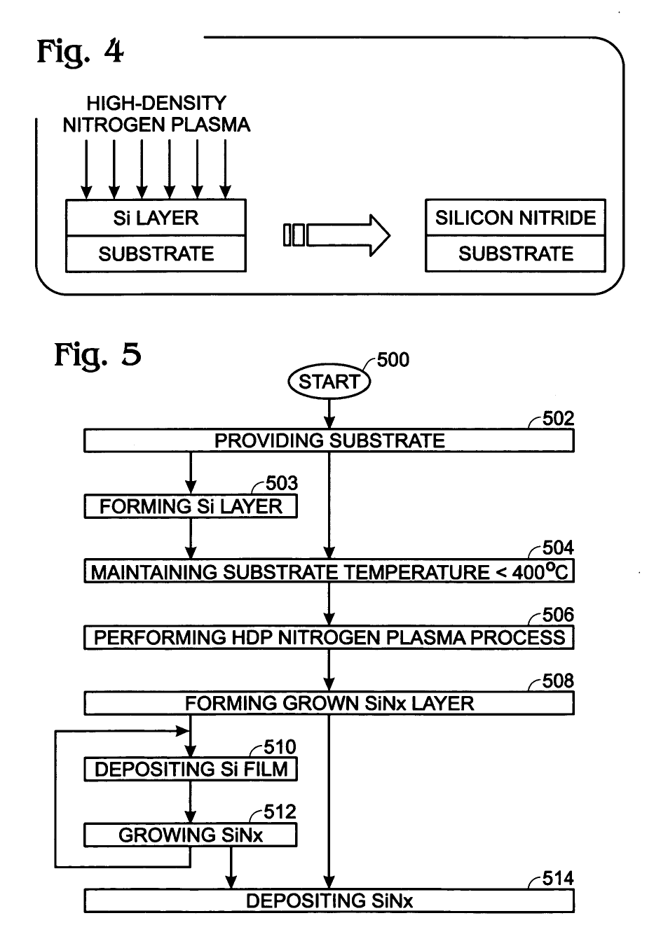

FIG. 4 is a diagram depicting a step in a sequential nitridation process. The silicon nitride growth rate decreases rapidly with an increase in nitridation time. The silicon nitride growth is self-limiting due to the high diffusion resistance of the silicon nitride film. However, thicker silicon nitride layers can be processed at a significantly lower thermal budget in multiple nitridation steps by sequentially depositing a thin silicon layer and then nitriding it. The Si layer can be deposited by any suitable technique and then exposed to the high-density nitrogen plasma. The Si layer thickness of each layer, and the number of layers of sequential Si deposition/nitridation are based on the desired silicon nitride film thickness, Si thin film processing conditions, and the thermal budget for nitridation.

Hydrogenation

The interfacial and the bulk quality of the silicon nitride thin films are important for the fabrication of stable and reliable electronic devices. The high-density plasma characteristics are suitable for the fabrication of high quality thin films with high structural density, low process-induced impurity content, and minimal bulk or interface damage. In general, the bulk and interface defect concentration of silicon nitride thin films can be further reduced by hydrogen passivation of the defect sites. The films can be hydrogenated by conventional thermal or plasma methods. The films can be hydrogenated by conventional thermal annealing in a N₂/H₂ atmosphere. The thermal hydrogenation process typically requires a high thermal budget due to the low diffusion coefficients of molecular hydrogen species at thermal energies. However, the high-density plasma hydrogenation process is attractive for an efficient low temperature and low thermal budget passivation of defects and dangling bonds in thin films. The high-density plasma-generated active hydrogen species are suitable for the efficient hydrogenation of thick films and novel multilayer structures. Table II summarizes the high-density plasma processing conditions suitable for the efficient hydrogenation of thin films.

TABLE II
High-density Plasma Hydrogenation Process Ranges

| | |
|---|---|
| Top Electrode Power | 13.56-300 MHz, up to 10 W/cm², |
| Bottom Electrode Power | 50 KHz-13.56 MHz, up to 3 W/cm² |
| Pressure | 1-500 mTorr |
| Gases: General | H₂ + Any suitable Inert Gas |
| Process Temperature | 25-400° C. |
| Time | 30 s-60 min |

FIG. 5 is a flowchart illustrating a method for forming a silicon nitride (SiNx) film. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 500.

Step 502 provides a substrate. Step 504 maintains a substrate temperature of about 400 degrees C., or less. However, as stated above, the process is not necessarily limited to temperature below about 400° C. For example, the substrate temperature can be in the range of about 25 to 400 degrees C. Step 506 performs a high-density (HD) nitrogen plasma process, typically by connecting a top electrode to an inductively coupled HD plasma source. Step 508 forms a grown layer of SiNx overlying the substrate. The Si₃N₄ notation used for silicon nitride signifies a perfect bonding between silicon and nitrogen atoms. The SiNx notation used herein signifies some dangling bonds may exist in the resultant silicon nitride. That is, SiNx may be a non-stiochiometric silicon nitride.

If the substrate provided in Step 502 is silicon, then Step 508 grows SiNx from the Si substrate. Alternately, Step 503 forms a Si layer overlying the substrate. Here, the substrate can be a material such as SiGe, glass, quartz, metal, dielectric insulators, or plastic. Then, Step 508 grows the SiNx layer from the Si layer.

In a sequential deposition aspect of the method, Step 510 deposits a Si film overlying the SiNx, following the growing of SiNx in Step 508. Step 512 grows SiNx from the deposited Si layer. Step 510 and 512 can be iterated a plurality of times. In another aspect, Step 514 deposits SiNx overlying the grown SiNx using any conventional process, following the forming of the grown SiNx layer (Step 508 or Step 512).

In one aspect, growing the SiNx layer in Step 508 (Step 512) includes growing SiNx at an initial growth rate of at least about 20 Å in about the first minute. To due self-limiting growth, Step 508 (Step 512) grows the SiNx layer to a thickness of about 50 Å. Alternately stated, the practical maximum thickness is about 50 Å.

Performing the HD nitrogen plasma process using an inductively coupled plasma (ICP) source in Step 506 may include the following substeps (not shown). Step 506a supplies power to a top electrode at a frequency in the range of about 13.56 to about 300 megahertz (MHz), and a power density of up to about 10 watts per square centimeter (W/cm²). Step 506b supplies power to a bottom electrode at a frequency in the range of about 50 kilohertz to 13.56 MHz, and a power density of up to about 3 W/cm². Step 506c uses an atmosphere pressure in the range of about 1 to 500 mTorr. Step 506d processes in the range of about 0 to 120 minutes. Step 506e supplies an atmosphere with a nitrogen source gas.

The following is a list of potential nitrogen source gases that may satisfy the requirements of Step 506e:

pure nitrogen;

ammonia;

ammonia and an inert gas such as He, Ar, or Kr;

nitrogen and an inert gas such as He, Ar, or Kr;

nitrogen and hydrogen;

nitrogen, hydrogen, and an inert gas such as He, Ar, or Kr; or,

helium and nitrogen.

In another aspect, Step 506e may supply helium and nitrogen, with a nitrogen dilution of less than about 20%. Alternately, Step 506e may supply helium and nitrogen, with a nitrogen dilution of about 3%.

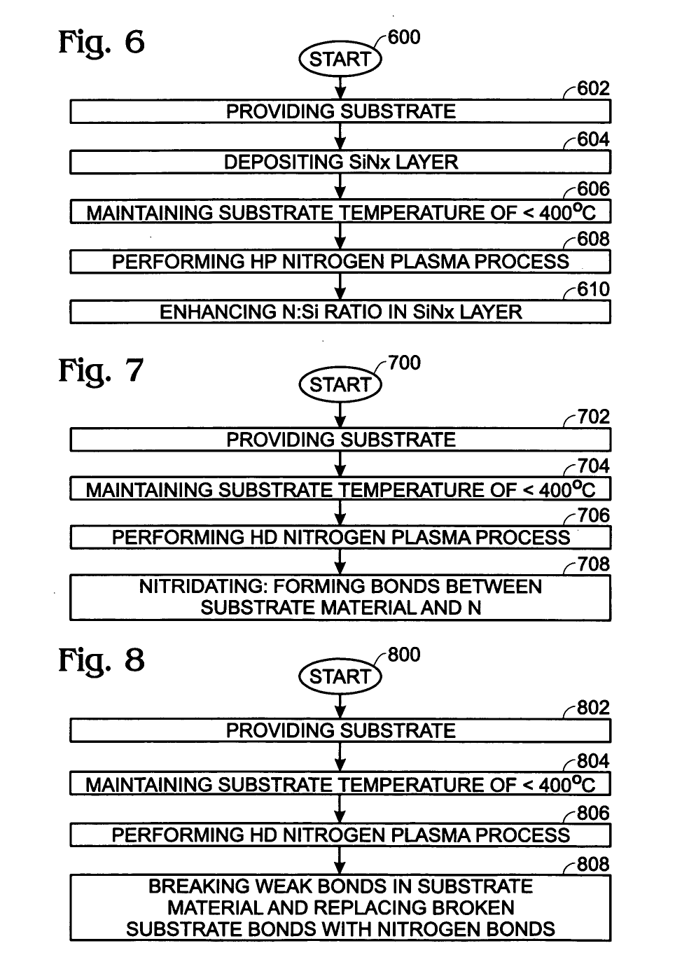

FIG. 6 is a flowchart illustrating a method for enhancing the nitrogen (N) content in a SiNx film. The method starts at Step 600. Step 602 provides a substrate. Step 604 deposits a SiNx layer overlying the substrate using a conventional process. Step 606 maintains a substrate temperature of about 400 degrees C., or less. Step 608 performs a high-density (HD) nitrogen plasma process. Step 610, in response to the HD nitrogen plasma process, enhances the ratio of N to Si in the SiNx layer. HDP process details of this method are similar to the explanation accompanying FIG. 5, and will not be repeated here in the interest of brevity.

FIG. 7 is a flowchart illustrating a method for the nitridation of a substrate. The method starts at Step 700. Step 702 provides a substrate. In this case, the substrate or foundation film layer need not be Si, as other materials can also be nitridated. For example, the substrate can be a metal, a semiconductor, or an insulator material. Step 704 may maintain a substrate temperature of about 400 degrees C., or less. Step 706 performs a high-density nitrogen plasma process. Step 708 performs a nitridation process. That is, Step 708 forms bonds between the substrate material and nitrogen in response to the HD nitrogen plasma process. HDP process details of this method are similar to the explanation accompanying FIG. 5, and will not be repeated here in the interest of brevity.

FIG. 8 is a flowchart illustrating a method for passivating the structure of a substrate. The method starts at Step 800. Step 802 provides a substrate. Again, passivation can be performed on materials other than Si, such as metals, semiconductors, and insulator materials. Step 804 may maintain a substrate temperature of about 400 degrees C., or less. Step 806 performs a high-density (HD) nitrogen plasma process. Step 808, in response to the HD nitrogen plasma process: breaks weak bonds in the substrate material structure; and, replaces the broken substrate material bonds with nitrogen bonds. HDP process details of this method are similar to the explanation accompanying FIG. 5, and will not be repeated here in the interest of brevity.

A high-density plasma silicon nitride growth, and related nitridation and passivation processes have been presented. Some details of specific materials and fabrication steps have been used to illustrate the invention. However, the invention is not limited to merely these examples. Other variations and embodiments of the invention will occur to those skilled in the art.

We claim:

1. A method for forming a silicon nitride (SiNx) film, the method comprising:
providing a substrate;
performing a high-density (HD) nitrogen plasma process; and,
forming a grown layer of SiNx overlying the substrate.

2. The method of claim 1 wherein performing an HD nitrogen plasma process includes connecting a top electrode to an inductively coupled HD plasma source.

3. The method of claim 1 wherein providing the substrate includes providing a silicon (Si) substrate; and,
wherein forming the grown layer of SiNx overlying the substrate includes growing SiNx from the Si substrate.

4. The method of claim 1 wherein performing the HD nitrogen plasma process includes using an inductively coupled plasma (ICP) source as follows:
supplying power to a top electrode at a frequency in the range of about 13.56 to 300 megahertz (MHz), and a power density of up to about 10 watts per square centimeter (W/cm²);
supplying power to a bottom electrode at a frequency in the range of about 50 kilohertz to 13.56 MHz, and a power density of up to about 3 W/cm²;
supplying an atmosphere pressure in the range of about 1 to 500 mTorr;
processing in the range of about 0 to 120 minutes: and,
supplying an atmosphere with a nitrogen source gas.

5. The method of claim 4 wherein supplying the atmosphere with a nitrogen source gas includes supplying a gas selected from the group comprising:
pure nitrogen;
ammonia;
ammonia and an inert gas selected from the group comprising He, Ar, and Kr;
nitrogen and an inert gas selected from the group comprising He, Ar, and Kr;
nitrogen and hydrogen;
nitrogen, hydrogen, and an inert gas selected from the group comprising He, Ar, and Kr; and,
helium and nitrogen.

6. The method of claim 4 wherein supplying the atmosphere with a nitrogen source gas includes supplying helium and nitrogen, with a nitrogen dilution of less than about 20%.

7. The method of claim 4 wherein supplying the atmosphere with a nitrogen source gas includes supplying helium and nitrogen, with a nitrogen dilution of about 3%.

8. The method of claim 1 wherein growing the SiNx layer includes growing the SiNx layer to a thickness of about 50 Å.

9. The method of claim 1 wherein growing the SiNx layer includes growing SiNx at an initial growth rate of at least about 20 Å in about the first minute.

10. The method of claim 1 further comprising:
forming a Si layer overlying the substrate; and,
wherein forming the grown layer of SiNx includes growing the SiNx layer from the Si layer.

11. The method of claim 1 further comprising:
following the growing of SiNx, depositing a Si film overlying the SiNx,
growing SiNx from the deposited Si layer.

12. The method of claim 1 wherein providing the substrate includes providing a substrate material selected from the group including Si, SiGe, glass, quartz, metal, dielectric insulators, and plastic.

13. The method of claim 1 further comprising:
maintaining a substrate temperature in the range of about 25 to 400 degrees C.

14. The method of claim 1 further comprising:
following the forming of the grown SiNx layer overlying the substrate, depositing SiNx overlying the grown SiNx.

15. A method for enhancing the nitrogen (N) content in a silicon nitride (SiNx) film, the method comprising:
providing a substrate;
depositing a SiNx layer overlying the substrate;
performing a high-density (HD) nitrogen plasma process; and,
in response to the HD nitrogen plasma process, enhancing the ratio of N to Si in the SiNx layer.

16. The method of claim 15 further comprising:
maintaining a substrate temperature of about 400 degrees C., or less.

17. A method for the nitridation of a substrate, the method comprising:
providing a substrate;
performing a high-density (HD) nitrogen plasma process; and,
in response to the HD nitrogen plasma process, performing a nitridation process that forms bonds between the substrate material and nitrogen.

18. The method of claim 17 wherein providing the substrate includes providing a substrate selected from the group comprising a metal, a semiconductor, and an insulator material.

19. The method of claim 17 further comprising:
maintaining a substrate temperature of about 400 degrees C., or less.

20. A method for passivating the structure of a substrate, the method comprising:
providing a substrate;
performing a high-density (HD) nitrogen plasma process; and,
in response to the HD nitrogen plasma process:
breaking weak bonds in the substrate material structure; and,
replacing the broken substrate material bonds with nitrogen bonds.

21. The method of claim 20 wherein providing the substrate includes providing a substrate selected from the group comprising a metal, a semiconductor, and an insulator material.

22. The method of claim 20 further comprising:
maintaining a substrate temperature of about 400 degrees C., or less.
